(19) United States
(12) Patent Application Publication
(10) Pub. No.: US 2020/0200813 A1
(43) Pub. Date: Jun. 25, 2020

(54) ONLINE DIAGNOSIS METHOD FOR DEFORMATION POSITION ON TRASNFORMATION WINDING

(71) Applicant: Zhejiang University, Hangzhou (CN)

(72) Inventors: Zhongsheng HUA, Hangzhou (CN); Yuxuan YOU, Hangzhou (CN); Ye HUA, Hangzhou (CN)

(21) Appl. No.: 16/554,151

(22) Filed: Aug. 28, 2019

(30) Foreign Application Priority Data
Dec. 21, 2018 (CN) 201811567345.X

(51) Int. Cl. G01R 31/02; G01B 7/16

(52) U.S. Cl. CPC G01R 31/027; G01B 7/16

(57) ABSTRACT

The invention discloses an online diagnosis method for transformer winding deformation position, including: (1) collecting a transformer with known winding state and decomposing into several position sub-samples; (2) performing feature extraction on each position sub-sample with information entropy, adding with label indicating deformation and inputting into support vector machine to train diagnosis model; (3) decomposing a transformer under diagnosis into 9 position subsamples in the way of step (1), performing feature extraction of step (2) and inputting into the diagnostic model trained in step (2); (4) outputting diagnosis result from the support vector machine about whether the position sub-samples of the transformer is deformed. The invention can achieve intelligent diagnosis of winding deformation by comprehensively considering variations of monitoring indicators of the transformer in complexity, time-frequency domain and other aspects and automatically learning diagnostic logic from fault features through machine learning algorithms, thereby reducing labor costs and improving diagnostic efficiency.

### CROSS-REFERENCE TO RELATED APPLICATIONS

This application claims the benefit of priority from Chinese Patent Application No. CN201811567345.X, filed on Dec. 21, 2018. The content of the aforementioned application, including any intervening amendments thereto, is incorporated herein by reference in its entirety.

### TECHNICAL FIELD

The invention relates to the field of fault diagnosis, and in particular to an online diagnosis method for deformation position on transformer winding(s).

### BACKGROUND OF THE PRESENT INVENTION

Transformer is one of the main equipment of power system, and plays the role of hub in grid interconnection and power exchange. When the transformer is subjected to short-circuit shock or transportation collision, the transformer winding may undergo axial or radial dimensional changes under the action of electric power or mechanical force, which is usually expressed as local distortion, bulging or displacement of the winding, called winding deformation.

Severe winding deformation will lead to insulation breakdown, causing power system accidents and huge economic and social losses. The difficulty involved in the transformer winding deformation is that the winding deformation has the characteristics of concealment and gradual change. The shape change inside the winding cannot be directly observed, and the deformed transformer may continue to operate for a long period of time, in a more dangerous “sub-health” state with no apparent difference from the previous operating state. If it is not repaired for a long time, the deformation will be intensified, and the short-circuit resistance will continue to decrease until the transformer winding is completely damaged.

Transformers are numerous and distributed, which further increases the difficulty in winding deformation diagnosis and test. Therefore, it is necessary to conduct in-depth research on the winding deformation, and establish a winding deformation diagnosis method of high-accuracy and high-efficiency, so as to timely repair and replace the deformed transformer, and ensure the safe and stable operation of the power system.

At present, the commonly used diagnostic methods for winding deformation include three ways: frequency response method, low-voltage short-circuit impedance test method and winding dielectric loss and capacitance test method. Using the frequency response analysis method to determine the transformer winding deformation mainly includes comparing the amplitude-frequency response characteristics of the windings vertically and horizontally, and comprehensively considering the factors such as short-circuit impact on the transformer, transformer structure, electrical test and analysis of gas dissolved in oil. The low-voltage short-circuit impedance test method refers to the method in which the relative change of short-circuit impedance, short-circuit reactance and leakage inductance and the degree of three-phase asymmetry under an AC power frequency voltage not higher than 500V are used as the basis for determining whether the winding is deformed. The winding dielectric loss and capacitance test method refers to the case where the internal deformation of the transformer is determined by the change of dielectric loss and capacitance. Because the capacitance of each winding of the transformer product is basically fixed after the transformer product is manufactured, if the side winding is severely deformed due to the short-circuit impact, its relative distance changes significantly, and the capacitance change is correspondingly large.

The above methods are widely used, but the common limitation is that they all need power-down test and are offline diagnostic methods; they have the disadvantages of requiring transformers to be out of service and requiring high professional skills of operators.

The online diagnosis method refers to the method of diagnosing the deformation of the winding by using device to monitor data online, and there are mainly two implementation ways. The first way is an online diagnostic method based on improvement of three offline diagnostic methods. However, compared with off-line diagnosis, the current, voltage and other values in the online diagnosis will be affected by many aspects of the grid, and the change of relevant monitoring indicators may not accurately reflect whether the winding is deformed. Taking the current deviation coefficient method as an example, the principle of this online diagnosis method is to determine the winding deformation by the correlation between current and capacitance. However, when the transformer is charged, the current value is affected not only by the capacitance but also by the grid load, so the change of the current value is not necessarily caused by the change of the capacitance. Directly using the current value as a basis cannot accurately determine the winding deformation and the hidden characteristics of the monitored data need to be excavated. The second way is to directly observe the internal structure of the winding with different high-tech equipment to determine whether deformation occurs. Due to the high cost of application of new technologies and new equipment, these methods have not been put into actual production.

Another feasible way of online diagnosis method is to directly analyze the measurable signal by using signal processing techniques such as wavelet transform and Fourier transform, extract characteristic values such as amplitude, variance and information entropy, and then combine with the classifier to detect the fault type. Signal-based fault diagnosis method does not rely on accurate system models and does not rely on expert knowledge, so no prior knowledge related to faults is needed, making the application of this method more extensive.

Information entropy is a nonlinear kinetic parameter based on complexity metrics. Permutation entropy in information entropy have some application basis in power system fault diagnosis. The looseness or deformation of the transformer winding will affect the change of the mechanical kinetics characteristics of the transformer winding. Therefore, the winding deformation may cause the change of the information entropy of the monitored sequence.

The patent application with the publication number CN 107037314 A discloses an online diagnostic method for winding deformation fault on power transformer, which includes using a vibration signal collecting device to collect three-phase mechanical vibration signals at two positions on the low-voltage side tank surface of the power transformer; using blind source separation algorithm to perform signal source separation on the collected three-phase mechanical vibration signals at the two positions of the power transformer, so to obtain the three-phase mechanical vibration signals of the power transformer windings; using wavelet packet decomposition to perform three-layer wavelet packet decomposition reconstruction on the three-phase mechanical vibration signals of the power transformer winding, to obtain spectra of the mechanical vibration signals of the power transformer winding; calculating energy entropy values of the mechanical vibration signals of the power transformer winding; and determining the state of the current power transformer winding according to the relation between the obtained energy entropy values of the mechanical vibration signals of the power transformer winding and an energy entropy upper limit threshold and an energy entropy lower limit threshold. The above method can determine whether the current power transformer winding is deformed and faulted, but cannot accurately determine the winding deformation position.

### SUMMARY OF THE PRESENT INVENTION

In view of the deficiencies in the art, the present invention provides an online diagnostic method for deformation position on transformer winding, which utilizes permutation entropy and wavelet energy to extract features of on-line monitored current and voltage signals, and can achieve intelligent diagnosis of winding deformation by comprehensively considering variations of various monitoring indicators of the transformer in complexity, time-frequency domain and other aspects and automatically learning diagnostic logic from fault features through machine learning algorithms, thereby reducing labor costs and improving diagnostic efficiency.

An online diagnostic method for deformation position on transformer winding, comprising:

(1) taking current, voltage, current difference and voltage difference of each phase of each winding in a transformer for which winding state is known as online monitoring indicators, and grouping the online monitoring indicators into several position sub-samples according to positions;

(2) obtaining two non-dimensional online monitoring data sequences by dividing online monitoring data recorded according to the online monitoring indicators into two sequences according to time and normalizing the two sequences;

(3) calculating permutation entropy, wavelet energy and arithmetic mean of each of the two non-dimensional online monitoring data sequences, and calculating root mean square errors of the permutation entropies, the wavelet energies and the arithmetic means, respectively;

(4) constructing a four-dimensional feature set by using the three root mean square errors obtained in step (3) and a cumulative short-circuit current of the corresponding position sub-sample as features, where the cumulative short-circuit current is a sum of short-circuit currents cumulatively suffered at a position corresponding to the position sub-sample;

(5) adding the four-dimensional feature set with a label and inputting the four-dimensional feature set into a support vector machine (SVM) for diagnostic model training, where the label is used to display winding deformation status of the position corresponding to the position subsample; and

(6) obtaining a four-dimensional feature set by performing feature extraction on a transformer under diagnosis with steps (1)-(4), and inputting the obtained four-dimensional feature set into a diagnostic model trained in step (5), and performing diagnose on the positions corresponding to respective position subsamples to determine whether there is a winding deformation.

In the step (1), the transformer for which winding state is known may be of 110 kV or 220 kV. The 220 kV transformer has three windings in three-phase, where the three phases are phase-A, phase-B and phase-C, and the three windings are 220 kV high-voltage, 110 kV medium-voltage and 35 kV low-voltage. The 110 kV transformer has three windings in three-phase, where the three phases are phase-A, phase-B and phase-C, and the three windings are 110 kV high-voltage, 35 kV medium-voltage and 10 kV low-voltage.

Preferably, there are 9 of the position subsamples, i.e., high-voltage phase-A, high-voltage phase-B, high-voltage phase-C, medium-voltage phase-A, medium-voltage phase-B, medium-voltage phase-C, low-voltage phase-A, low-voltage phase-B, and low-voltage phase-C, respectively.

Preferably, the online monitoring indicators of the high-voltage phase-A are high-voltage phase-A current, high-voltage phase-A voltage, high-voltage phases A/B current difference, and high-voltage phases A/B voltage difference;

the online monitoring indicators of high-voltage phase-B are high-voltage phase-B current, high-voltage phase-B voltage, high-voltage phases A/B current difference, and high-voltage phases A/B voltage difference;

the online monitoring indicators of high-voltage phase-C are high-voltage phase-B current, high-voltage phase-B voltage, high-voltage phases B/C current difference, and high-voltage phases B/C voltage difference;

the online monitoring indicators of medium-voltage phase-A are medium-voltage phase-A current, medium-voltage phase-A voltage, medium-voltage phases A/B current difference and medium-voltage phases A/B voltage difference;

the online monitoring indicators of medium-voltage phase-B are medium-voltage phase-B current, medium-voltage phase-B voltage, medium-voltage phases A/B current difference and medium-voltage phases A/B voltage difference;

the online monitoring indicators of medium-voltage phase-C are medium-voltage phase-B current, medium-voltage phase-B voltage, medium-voltage phases B/C current difference and medium-voltage phases B/C voltage difference;

the online monitoring indicators of low-voltage phase-A are low-voltage phase-A current, low-voltage phase-A voltage, low-voltage phases A/B current difference, and low-voltage phases A/B voltage difference;

the on-line monitoring indicators of low-voltage phase-B are low-voltage phase-B current, low-voltage phase-B voltage, low-voltage phases A/B current difference, and low-voltage phases A/B voltage difference; and

the on-line monitoring indicators of the low-voltage phase-C are low-voltage phase-B current, low-voltage phase-B voltage, low-voltage phases B/C current difference, and low-voltage phases B/C voltage difference.

In the step (2), preferably, the dividing online monitoring data recorded according to the online monitoring indicators into two sequences according to time may include: for the transformer that has subjected to short circuit, dividing, according to occurrence time of a latest short circuit, the online monitoring data into a front-segment sequence before the short-circuit and a back-segment sequence after the short-circuit; and for the transformer that has not subjected to short-circuit, dividing, according to time length, the online monitoring data into a front-segment sequence and a back-segment sequence.

The normalization may be maximum or minimum normalization, and the online monitoring data may be converted into a [0, 1] interval by following formula to obtain the non-dimensional online monitoring data x*:

$${x}^{*} = \frac{x - {x}_{min}}{{x}_{max} - {x}_{min}}$$

where x is the online monitoring data recorded according to the online monitoring indicators, xₘₐₓ is a maximum value of the online monitoring data recorded according to a same online monitoring indicator, and xₘᵢₙ is a minimum value of the online monitoring data recorded according to the same online monitoring indicator.

In the step (3), the permutation entropy is a nonlinear kinetic parameter based on complexity measure, and has advantages of being unaffected by a length of a time sequence and being fast in calculation. The permutation entropy can be calculated by the following method:

a. using phase space reconstruction delay coordinate method to reconstruct the phase space of any non-dimensional online monitoring data x(i) in sequence X, to obtain the following matrix:

$$[ \begin{matrix}x ( 1 ) & x ( 1 + τ ) & … & x ( 1 + ( m - 1 ) τ ) \\ … & … & … & … \\ x ( j ) & x ( j + τ ) & … & x ( j + ( m - 1 ) τ ) \\ … & … & … & … \\ x ( K ) & x ( K + τ ) & … & x ( K + ( m - 1 ) τ )\end{matrix} ]$$

where j=1, 2, . . . , K, K is the number of reconstructed components, m is the embedded dimension, τ is the delay time, and x (j) is the j-th row component of the reconstructed matrix.

b. arranging elements of the reconstructed vector of x(i) in ascending order: j1, j2, . . . , jm, where at most m! different permutation patterns would be obtained in m-dimensional phase space mapping, and P(1) represents one of the permutation patterns:

P(1)=(j1, j2, . . . , jm)

where 1=1, 2, . . . , k, k≤m!.

c. performing statistics on the number of occurrences of various permutations of the sequence X, and calculating a relative frequency Pi of various permutations as the occurrence probability pi:

$$pi = Pi = \frac{number of P ( I )}{k}$$

where 1=1, 2, . . . , k, k≤m!.

The entropy H₁ of the signal permutation pattern can be expressed as:

$${H}_{1} = - {\sum }_{i = 1}^{k} {P}_{i} ln {P}_{i} ;$$

The normalized sequence permutation entropy H(m,τ) is calculated as:

$$H ( m , τ ) = \frac{( - {\sum }_{i = 1}^{k} {P}_{i} ln {P}_{i} )}{ln ( m ! )}$$

The permutation entropy can only reflect the complexity of the current one-dimensional time sequence, and does not decompose the signal. Due to external temperature, weather and other factors, the signal is often accompanied by noise, and the wavelet energy can be used to separate the noise. Wavelet energy is a combination of wavelet decomposition and energy entropy, which can reflect the complexity of signal at different scales. The more uniform the energy distribution in the frequency band, and the greater the complexity of the sequence. The calculation of wavelet energy is as follows: the current or voltage sequence f(n) is continuously subdivided by different filters to decompose the signal into sub-signals on different scales (M), including high frequency detail sub-band signals D1, D2, . . . , DM and low frequency approximation sub-band signal A_{M}(n) obtained by performing a series of frequency band binary divisions, namely:

$$f ( n ) = {D}_{1} ( n ) + {D}_{2} ( n ) + … + {D}_{M} + {A}_{M} ( n ) = {\sum }_{j = 1}^{M} {D}_{j} ( n ) + {A}_{M} ( n )$$

After wavelet decomposition of the signal, the wavelet energies E1, E2, . . . , En in the signal at every frequency bands i=1, 2, . . . , n can be obtained. According to the energy conservation before and after the wavelet transform, the total energy E of the signal in a certain time window is equal to the sum of the energies Ei of the components. The relative energy eᵢ of the wavelet is supposed as:

$${e}_{i} = \frac{{E}_{i}}{\sum {E}_{i}}$$

where Σᵢ₌₁ⁿeᵢ=1. The wavelet energy H2 is equal to the sum of the wavelet relative energies of respective frequency bands:

H₂=−Σeᵢ1neᵢ.

The root mean square error RMSE can be calculated as follows:

$$RMSE = \sqrt{\frac{{\sum }_{i = 1}^{n} {( {Xi}_{before} - {Xi}_{after} )}^{2}}{n}}$$

where i represents the i-th online monitoring indicator (i=1, 2, . . . , n) and n represents the total number of online monitoring indicators. Xi_{before} indicates the permutation entropy, wavelet energy or arithmetic mean of the front-segment sequence of online monitoring data recorded according to the i-th online monitoring indicator. Xi_{after} indicates the permutation entropy, wavelet energy or arithmetic mean of the back-segment sequence of the online monitoring data recorded according to the i-th online monitoring indicator. Xi_{before}−Xi_{after} represents the difference of permutation entropies, difference of wavelet energies or difference of arithmetic means between the front-segment and back-segment sequences of the indicator, and Xi_{before}−Xi_{after} is squared to eliminate the influence of negative numbers.

With the above method, the root mean square error RMSE of the permutation entropy, wavelet energy or arithmetic mean of the front-segment and back-segment sequences can be obtained.

In the step (4), the cumulative short-circuit current is the sum of short-circuit currents cumulatively suffered at the position corresponding to the position sub-sample; and the short-circuit current is online data automatically recorded when the transformer is short-circuited, and directly determines a degree of winding deformation.

In step (5), the support vector machine is one of machine learning approaches, which is based on minimization of structural risk, and can solve practical problems such as less samples, nonlinearity and high dimensional numbers well.

Preferably, the diagnostic model training includes: finding a hyperplane that is able to separate deformation data and normal data and maximizes an interval between these two types of data. The point closest to the separation plane is called support vector.

Supposing a given training set {xi, yi}, i=1, 2, . . . , N, yi∈{−1, +1}, xi∈R^{d}, if there is a classification hyperplane ω x+b=0 such that:

Yi(ωxi+b−1)≥0, (i=1,2, . . . ,n)

then the foregoing training set is linearly separable, and an optimal classification problem is transformed into a constrained optimization problem, that is, under the constraint of the above formula, the following equation is solved:

$$min \frac{1}{2} {ω}^{T} ω + C {\sum }_{i = 1}^{n} {ξ}_{i}$$

$$s . t . \{ \begin{matrix}{y}_{i} ( {ω}^{T} f ( {x}_{i} ) + b ) \geq 1 - {ξ}_{i} \\ {ξ}_{i} \geq 0 , i = 1 , 2 , … , n\end{matrix}$$

where ξᵢ is a slack variable introduced considering the fact that some samples cannot be correctly classified; C is a penalty coefficient for misclassification, C≥0; and n is the number of classified samples.

For linearly inseparable data, a kernel function may be found to map the data to a high-dimensional space, and then the hyperplane is used to separate the deformation data and the normal data. The available kernel functions include, in addition to linear functions, nonlinear functions such as polynomials, RBF function or trigonometric function. The combination of the kernel function and the penalty coefficient C is continuously changed by grid optimization method to determine a parameter combination that minimizes training error of the support vector machine.

In the step (6), preferably, performing diagnose on the positions corresponding to respective position subsamples to determine whether there is a winding deformation includes: if the subsample point to be diagnosed is located on a deformation side of the hyperplane, it is determined that a deformation occurs at the position; and if the subsample point to be diagnosed is located on a normal side of the hyperplane, it is determined that no deformation occurs at the position.

The main advantages of the present invention over the prior art are as follows:

(1) using the entropy and wavelet energy to extract the features of the on-line monitored current and voltage signals, the variations of various monitoring indicators of the transformer in complexity, time-frequency domain and other aspects can be comprehensively considered, without the need for additional experimental equipment and experimental operations, thereby reducing the cost of manpower and material resources.

(2) by dividing the sum of the features extracted from all monitoring sequences of each transformer by the number of monitoring indicators, the features of the transformers with different monitoring numbers are unified to the same level that can be compared, and the transformers with incomplete monitoring indicators are still applicable, which means wide applicability.

(3) by automatically learning the diagnosis logic from the fault features through the support vector machine, intelligent diagnosis of winding deformation is realized, making up for the lack of manual experience and improving diagnosis efficiency and accuracy.

### BRIEF DESCRIPTION OF THE DRAWINGS

FIG. 1 is a flow chart of an online diagnosis method for deformation position on transformer winding according to embodiment 1;

FIG. 2 is a diagram showing variations of permutation entropies of each online monitoring indicator before and after a short circuit of the transformer a according to embodiment 1; and

FIG. 3 is a two-dimensional dispersion diagram of root mean square errors of permutation entropies and arithmetic means of front-segment sequence before short circuit and back-segment sequence after the short circuit for 27 position subsamples of three transformers according to embodiment 1.

### DETAILED DESCRIPTION OF THE PRESENT INVENTION

The invention is further illustrated below in conjunction with the drawings and specific embodiments. It is to be understood that the embodiments are illustrative and are not intended to limit the scope of the invention. The experimental methods in the following embodiments for which the specific conditions are not specified are generally in conformity with conventional conditions or in conformity with conditions recommended by the manufacturer.

### Embodiment 1

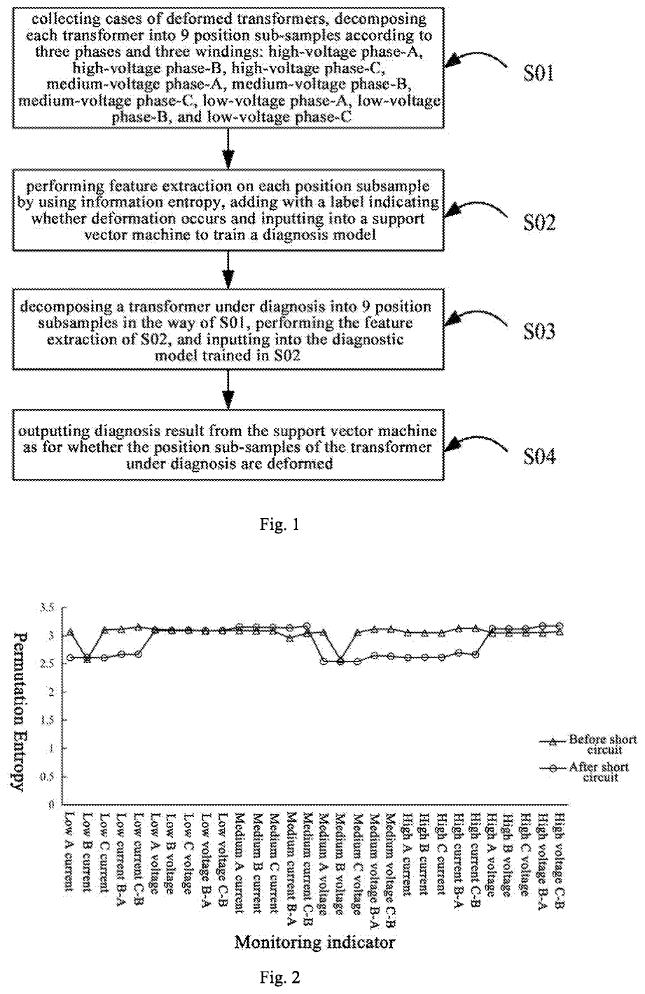

As shown in FIG. 1, the flow of an online diagnostic method for deformation position on transformer winding is as follows:

S01, collecting transformers for which winding state is known, decomposing each transformer into 9 position sub-samples according to three phases and three windings: high-voltage phase-A, high-voltage phase-B, high-voltage phase-C, medium-voltage phase-A, medium-voltage phase-B, medium-voltage phase-C, low-voltage phase-A, low-voltage phase-B, and low-voltage phase-C;

S02, performing feature extraction on each position subsample by using information entropy, adding with a label indicating whether deformation occurs and inputting into a support vector machine to train a diagnosis model;

S03, decomposing a transformer under diagnosis into 9 position subsamples in the way of S01, performing the feature extraction of S02, and inputting into the diagnostic model trained in S02; and

S04, outputting diagnosis result from the support vector machine as for whether the position sub-samples of the transformer under diagnosis are deformed.

(1) Three transformers, for which deformation has happened and specific deformation position is specified, is selected, which are transformer a, transformer b and transformer c, respectively. The voltage level of transformer a is 110 kV, and the voltage level of transformer b and transformer c is 220 kV. The recorded online monitoring indicators that can be directly read are shown in Table 1.

TABLE 1
Recorded online monitoring indicators that can be directly read

| | High voltage | Medium voltage | Low voltage |
|---|---|---|---|
| | winding | winding | winding |
| Phase A | indicator1: | indicator2: | indicator3: |
| current | High voltage | Medium voltage | Low-voltage |
| | winding phase-A | winding phase-A | winding phase-A |
| | current value | current value | current value |
| Phase A | indicator4: | indicator5: | indicator6: |
| voltage | High voltage | Medium voltage | Low voltage |
| | winding phase-A | winding phase-A | winding phase-A |
| | voltage value | voltage value | voltage value |
| Phase B | indicator7: | indicator8: | indicator9: |
| current | High voltage | Medium voltage | Low-voltage |
| | winding phase B | winding phase B | winding phase B |
| | current value | current value | current value |
| Phase B | indicator10: | indicator11: | indicator12: |
| voltage | High voltage | Medium voltage | Low-voltage |
| | winding phase B | winding phase B | winding phase B |
| | voltage value | voltage value | voltage value |
| Phase C | indicator13: | indicator14: | indicator15: |
| current | High voltage | Medium voltage | Low-voltage |
| | winding phase C | winding phase C | winding phase C |
| | current value | current value | current value |
| Phase C | indicator16: | indicator17: | indicator18: |
| voltage | High voltage | Medium voltage | Low-voltage |
| | winding phase C | winding phase C | winding phase C |
| | voltage value | voltage value | voltage value |

(2) Differences between the on-line monitoring data of the currents and voltages of respective phases and respective windings of each transformer are calculated, to construct the current-phase differences and voltage-phase differences, which are combined with the recorded online monitoring indicators that can be directly read into new complete online monitoring indicators.

(3) The online monitoring indicators of each transformer are grouped according to three phases and three-windings into 9 position sub-samples. The online monitoring indicators corresponding to each position sub-sample are shown in Table 2. Among the 27 sub-samples of the 3 transformers, 8 sub-samples were found to have undergone winding deformation after offline test and disassemble, which are the medium-voltage phase-A, medium-voltage phase-B, high-voltage phase-A, and high-voltage phase-C of transformer a, medium-voltage phase-B of transformer b, low-voltage phase-A, low-voltage phase-B and low-voltage phase-C of transformer c. The remaining 19 position subsample windings are normal.

TABLE 2
Grouping results of online monitoring indicators

| Position subsample | Subordinate online monitoring indicators |
|---|---|
| low-voltage | Low-voltage winding phase-A current value, |
| phase-A | low-voltage winding phase-A voltage value, |
| | low-voltage winding phases-AB current |
| | difference, low-voltage windingphases-AB |
| | voltage value |
| low-voltage | Low-voltage winding phase-B current value, |
| phase-B | low-voltage winding phase-B voltage value, |
| | low-voltage winding phases-AB current |
| | difference, low-voltage winding phases-AB |
| | voltage value |
| low-voltage | Low-voltage winding phase-C current value, |
| phase-C | low-voltage winding phase-C voltage value, |
| | low-voltage winding phases-BC current |
| | difference, low-voltage winding phases-BC |
| | voltage value |
| Medium-voltage | Medium voltage winding phase-A current value, |
| phase-A | medium-voltage winding phase-A voltage value, |
| | medium-voltage winding phases-AB current |
| | difference, medium-voltage winding phases-AB |
| | voltage value |
| Medium voltage | Medium voltage winding phase-B current value, |
| phase-B | medium-voltage winding phase-B voltage value, |
| | medium-voltage winding phases-AB current |
| | difference, medium-voltage winding phases-AB |
| | voltage value |
| Medium voltage | Medium-voltage winding phase-C current value, |
| phase-C | medium-voltage winding phase-C voltage value, |
| | medium-voltage winding phases-BC current |
| | difference, medium-voltage winding phases-BC |
| | voltage value |
| High voltage | High-voltage winding phase-A current value, |
| phase-A | high-voltage winding phase-A voltage value, |
| | high-voltage winding phases-AB current |
| | difference, high-voltage winding phases-AB |
| | voltage value |
| High voltage | High-voltage winding phase-B current value, |
| phase-B | high-voltage winding phase-B voltage value, |
| | high-voltage winding phases-AB current |
| | difference, high-voltage winding phases-AB |
| | voltage value |
| High voltage | High-voltage winding phase-C current value, |
| phase-C | high-voltage winding phase-C voltage value, |
| | high-voltage winding phases-BC current |
| | difference, high-voltage winding phases-BC |
| | voltage value |

(4) Feature extraction. The online monitoring data recorded according to the subordinate online monitoring indicators of each position subsample is divided into a front-segment sequence before the short circuit and a back-segment sequence after the short circuit according to the latest short circuit time, and maximum and minimum normalization is performed. The root mean square error of the permutation entropy, the root mean square error of the wavelet energy, and the root mean square error of the arithmetic mean of the processed sequences are calculated. The obtained three root mean square errors and the cumulative short-circuit current of the corresponding position sub-sample are characterized as a four-dimensional feature set.

Taking the low-voltage phase-A position subsample of transformer a as an example, the feature extraction is performed as follows:

a. According to the latest short-circuit time, Jan. 24, 2015, the online monitoring data recorded according to the monitoring indicators subordinate to low-voltage phase-A is divided into the front-segment sequence T_{before} before the short-circuit (2013 Nov. 1-2015 Jan. 24) and the back-segment sequence T_{after} after the short-circuit (2015 Jan. 24-2015 Aug. 13), and is subjected to the maximum and minimum normalization to be converted to the [0,1] interval for de-dimension.

The formula for maximum and minimum normalization is:

$${x}^{*} = \frac{x - {x}_{min}}{{x}_{max} - {x}_{min}}$$

where x* is non-dimensional online monitoring data, and x is online monitoring data recorded according to online monitoring indicators, where xₘₐₓ is a maximum value of the online monitoring data recorded according to a same online monitoring indicator, and xₘᵢₙ is a minimum value of the online monitoring data recorded according to the same online monitoring indicator.

b. The root mean square error of the permutation entropy, the root mean square error of the wavelet energy, and the root mean square error of the arithmetic mean of the two non-dimensional online monitoring data sequences are calculated according to the method described in the Summary of the Invention. The results are shown in Table 3. The root mean square error of the permutation entropy, the root mean square error of the wavelet energy, and the root mean square error of the arithmetic mean for the low-voltage phase-A position subsample are 0.303, 6.9095, and 0.039, respectively.

TABLE 3
Feature calculation and extraction results of the low-voltage phase-A
position subsample of transformer a

| | Permutation Entropy | | | wavelet energy | | | mean value | | |
|---|---|---|---|---|---|---|---|---|---|
| | Before | After | | Before | After | | Before | After | |
| | short | short | Differ- | short | short | Differ- | short | short | Differ- |
| indicator | circuit | circuit | ence | circuit | circuit | ence | circuit | circuit | ence |
| Low | 3.0707 | 2.6097 | 0.461 | 17.8113 | 12.9582 | 4.8531 | 0.212 | 0.1677 | 0.0443 |
| voltage | | | | | | | | | |
| phase-A | | | | | | | | | |
| current | | | | | | | | | |
| value | | | | | | | | | |
| Low | 3.1141 | 2.6696 | 0.4445 | 13.8621 | 1.2611 | 12.601 | 0.9255 | 0.9793 | −0.0539 |
| voltage | | | | | | | | | |
| phases-A | | | | | | | | | |
| B current | | | | | | | | | |
| difference | | | | | | | | | |
| Low | 3.1121 | 3.0938 | 0.0184 | 20.5114 | 20.5539 | −0.0425 | 0.6004 | 0.5646 | 0.0358 |
| voltage | | | | | | | | | |
| phase-A | | | | | | | | | |
| voltage | | | | | | | | | |
| value | | | | | | | | | |
| Low | 3.083 | 3.0868 | −0.0038 | 3.6475 | 0.711 | 2.9364 | 0.4967 | 0.4972 | −0.0005 |
| voltage | | | | | | | | | |
| phases-A | | | | | | | | | |
| B voltage | | | | | | | | | |
| difference | | | | | | | | | |
| RMSE | | | 0.3203 | | | 6.9095 | | | 0.0395 |

c. The three root mean square errors in Table 3 and the cumulative short circuit current of the low-voltage phase-A position subsample are characterized as a four-dimensional feature set. The cumulative short-circuit current of the low-voltage phase-A position subsample is obtained from the short-circuit record of the ledger information of transformer a, which is 9.2 kA. Therefore, the four-dimensional feature set of the low-voltage phase-A position subsample is [0.33, 6.9095, 0.039, 9.2].

The feature sets of the other 26 position subsamples are extracted according to steps a to c, and the summary results are shown in Table 4.

TABLE 4
Summary of feature extraction results for 27 position subsamples

| | | | Front and | | |
|---|---|---|---|---|---|
| | | Front and | back | | Cumulative |
| | | back | wavelet | Front and | short |
| trans- | Position | permutation | energy | back mean | circuit |
| former | subsample | entropy | difference | difference | current |
| trans- | Low | 0.320317 | 6.90946 | 0.039202 | 9.2 |
| former | voltage | | | | |
| a | phase-A | | | | |
| | Low | 0.222896 | 7.233183 | 0.034076 | 0 |
| | voltage | | | | |
| | phase-B | | | | |
| | Low | 0.345881 | 6.941979 | 0.045849 | 9.2 |
| | voltage | | | | |
| | phase-C | | | | |
| | Medium | 0.36323 | 27.80493 | 0.100947 | 0 |
| | voltage | | | | |
| | phase-A | | | | |
| | Medium | 0.254158 | 27.1847 | 0.068832 | 0 |
| | voltage | | | | |
| | phase-B | | | | |
| | Medium | 0.363299 | 27.96553 | 0.102912 | 0 |
| | voltage | | | | |
| | phase-C | | | | |
| | High | 0.319302 | 15.91197 | 0.050269 | 0 |
| | voltage | | | | |
| | phase-A | | | | |
| | High | 0.315275 | 15.91999 | 0.050043 | 0 |
| | voltage | | | | |
| | phase-B | | | | |
| | High | 0.325802 | 15.91999 | 0.052152 | 0 |
| | voltage | | | | |
| | phase-C | | | | |
| trans- | Low | 0.020471 | 36.03064 | 0.03519 | 0 |
| former | voltage | | | | |
| b | phase-A | | | | |
| | Low | 0.019591 | 37.50859 | 0.032284 | 0 |
| | voltage | | | | |
| | phase-B | | | | |
| | Low | 0.033643 | 41.35286 | 0.038622 | 0 |
| | voltage | | | | |
| | phase-C | | | | |
| | Medium | 0.078673 | 30.13068 | 0.089533 | 0 |
| | voltage | | | | |
| | phase-A | | | | |
| | Medium | 0.091766 | 29.02597 | 0.08934 | 10.118 |
| | voltage | | | | |
| | phase-B | | | | |
| | Medium | 0.116339 | 28.367999 | 0.090171 | 0 |
| | voltage | | | | |
| | phase-C | | | | |
| | High | 0.054301 | 32.94126 | 0.088438 | 5.884 |
| | voltage | | | | |
| | phase-A | | | | |
| | High | 0.019926 | 31.57624 | 0.088071 | 0 |
| | voltage | | | | |
| | phase-B | | | | |
| | High | 0.108691 | 31.79485 | 0.08942 | 0 |
| | voltage | | | | |
| | phase-C | | | | |
| trans- | Low | 0.182103 | 34.87654 | 0.068949 | 26.81 |
| former | voltage | | | | |
| c | phase-A | | | | |
| | Low | 0.219823 | 40.41053 | 0.067634 | 26.81 |
| | voltage | | | | |
| | phase-B | | | | |
| | Low | 0.219412 | 40.88089 | 0.069945 | 24.38 |
| | voltage | | | | |
| | phase-C | | | | |
| | Medium | 0.08231 | 17.27661 | 0.021917 | 51.68 |
| | voltage | | | | |
| | phase-A | | | | |
| | Medium | 0.07197 | 20.32252 | 0.020755 | 10.056 |
| | voltage | | | | |
| | phase-B | | | | |
| | Medium | 0.107109 | 38.55591 | 0.040062 | 17.256 |
| | voltage | | | | |
| | phase-C | | | | |
| | High | 0.090561 | 22.76819 | 0.041354 | 0 |
| | voltage | | | | |
| | phase-A | | | | |
| | High | 0.094293 | 22.82805 | 0.041885 | 0 |
| | voltage | | | | |
| | phase-B | | | | |
| | High | 0.095809 | 25.51844 | 0.043278 | 0 |
| | voltage | | | | |
| | phase-C | | | | |

As shown in FIG. 2, the permutation entropies of the front-segment sequence before the short-circuit and the back-segment sequence after the short-circuit for most of the online monitoring indicators of the transformer a are significantly different, which specifically is: for the low-voltage side current difference, the medium-voltage side voltage difference, the high-voltage side current and the high-voltage side voltage difference after the short-circuit, the permutation entropy after the short circuit is significantly lower than that before the short circuit, and it is inferred that fault occurs to the transformer a after the short circuit, resulting in a change in the operating state.

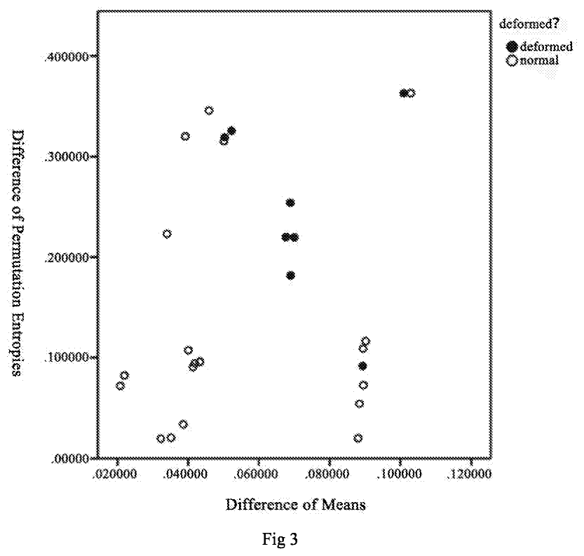

As shown in FIG. 3, the horizontal axis is the root mean square errors of the arithmetic means of the front segment sequence before the short circuit and the back segment sequence after the short circuit; the longitudinal axis is the root mean square errors of the permutation entropies of the front segment sequence before the short circuit and the back segment sequence after the short circuit; the hollow circles represent the normal position subsamples, and are mostly concentrated in the lower left corner of the drawing; the solid circles represent the deformed position subsamples, which are mostly concentrated in the upper right corner of the drawing, indicating that, as compared to normal position subsample, the root mean square error of the permutation entropy and the root mean square error of the arithmetic mean of the front segment sequence before the short circuit and the back segment sequence after the short circuit for the deformed position subsample are larger. That's to say, the deformation of the transformer winding leads to change of the permutation entropy and arithmetic mean of the online monitoring data recorded according to the online monitoring indicators, and the role of permutation entropy and arithmetic mean in diagnosing winding deformation is further proved.

It can also be seen from FIG. 3 that the boundary between the normal position subsamples and the deformed position subsamples exhibits features of a quadratic curve, so using quadratic curve SVM in the training of deformation position diagnostic model is better than the ordinary linear SVM in the aspect of classification effect.

(5) The four-dimensional feature set obtained in step (4), after being added with labels indicating whether being deformed, is inputted to the SVM for the training and verification of the diagnostic model. Three-fold cross-validation method is used to perform statistics on the determination result of the model. Cross-validation refers to the method of dividing training samples and test samples into multiple sub-samples, dividing these sub-samples according to different proportions, and using a large number of sub-samples to verify a few sub-samples. The results are shown in Tables 5 and 6.

TABLE 5
Support vector machine cross-validation result statistics

| | Determined by the | Determined by the model |
|---|---|---|
| Cross validation result | model as normal | as being deformed |
| Actually normal | 89.47% | 10.53% |
| Actually deformed | 12.50% | 87.50% |

TABLE 6
support vector machine cross-validation results

| | | Actual | Model | |
|---|---|---|---|---|
| | Position | operation | diagnosis | Result of |
| transformer | subsample | state | result | determination |
| transformer | Low voltage | normal | normal | correct |
| a | phase-A | | | |
| | Low voltage | normal | normal | correct |
| | phase-B | | | |
| | Low voltage | normal | normal | correct |
| | phase-C | | | |
| | Medium | deformed | deformed | correct |
| | voltage | | | |
| | phase-A | | | |
| | Medium | deformed | deformed | correct |
| | voltage | | | |
| | phase-B | | | |
| | Medium | normal | deformed | wrong |
| | voltage | | | |
| | phase-C | | | |
| | High | deformed | deformed | correct |
| | voltage | | | |
| | phase-A | | | |
| | High | normal | deformed | wrong |
| | voltage | | | |
| | phase-B | | | |
| | High | deformed | deformed | correct |
| | voltage | | | |
| | phase-C | | | |
| transformer | Low voltage | normal | normal | correct |
| b | phase-A | | | |
| | Low voltage | normal | normal | correct |
| | phase-B | | | |
| | Low voltage | normal | normal | correct |
| | phase-C | | | |
| | Medium | normal | normal | correct |
| | voltage | | | |
| | phase-A | | | |
| | Medium | deformed | normal | wrong |
| | voltage | | | |
| | phase-B | | | |
| | Medium | normal | normal | correct |
| | voltage | | | |
| | phase-C | | | |
| | High | normal | normal | correct |
| | voltage | | | |
| | phase-A | | | |
| | High | normal | normal | correct |
| | voltage | | | |
| | phase-B | | | |
| | High | normal | normal | correct |
| | voltage | | | |
| | phase-C | | | |
| transformer | Low voltage | deformed | deformed | correct |
| c | phase-A | | | |
| | Low voltage | deformed | deformed | correct |
| | phase-B | | | |
| | Low voltage | deformed | deformed | correct |
| | phase-C | | | |
| transformer | Medium | normal | normal | correct |
| c | voltage | | | |
| | phase-A | | | |
| | Medium | normal | normal | correct |
| | voltage | | | |
| | phase-B | | | |
| | Medium | normal | normal | correct |
| | voltage | | | |
| | phase-C | | | |
| | High | normal | normal | correct |
| | voltage | | | |
| | phase-A | | | |
| | High | normal | normal | correct |
| | voltage | | | |
| | phase-B | | | |
| | High | normal | normal | correct |
| | voltage | | | |
| | phase-C | | | |

It can be seen from Tables 5 and 6 that the online diagnostic method for deformation position on transformer winding described in this embodiment has high diagnostic accuracy, and the recognition rates for the normal position subsamples and the deformed position subsamples are 89.47% and 87.5%, respectively. An effective diagnosis of whether the winding of the transformer is deformed is possible.

In addition, it is to be understood that various modifications and changes may be made by those skilled in the art in view of the above description of the present invention, and these equivalents also fall within the scope defined by the appended claims.

What is claimed is:

1. An online diagnostic method for deformation position on transformer winding, comprising:
(1) taking current, voltage, current difference and voltage difference of each phase of each winding in a transformer for which winding state is known as online monitoring indicators, and grouping the online monitoring indicators into several position sub-samples according to positions;
(2) obtaining two non-dimensional online monitoring data sequences by dividing online monitoring data recorded according to the online monitoring indicators into two sequences according to time and normalizing the two sequences;
(3) calculating permutation entropy, wavelet energy and arithmetic mean of each of the two non-dimensional online monitoring data sequences, and calculating root mean square errors of the permutation entropies, the wavelet energies and the arithmetic means, respectively;
(4) constructing a four-dimensional feature set by using the three root mean square errors obtained in step (3) and a cumulative short-circuit current of a corresponding position sub-sample as features, wherein the cumulative short-circuit current is a sum of short-circuit currents cumulatively suffered at a position corresponding to the position sub-sample;
(5) adding the four-dimensional feature set with a label and inputting the four-dimensional feature set into a support vector machine for diagnostic model training, wherein the label is used to display winding deformation status of the position corresponding to the position subsample; and
(6) obtaining a four-dimensional feature set by performing feature extraction on a transformer under diagnosis with steps (1)-(4), inputting the obtained four-dimensional feature set into a diagnostic model trained in step (5), and performing diagnose on the positions corresponding to respective position subsamples to determine whether there is a winding deformation.

2. The online diagnostic method for deformation position on transformer winding according to claim 1, wherein there are 9 of the position subsamples: high-voltage phase-A, high-voltage phase-B, high-voltage phase-C, medium-voltage phase-A, medium-voltage phase-B, medium-voltage phase-C, low-voltage phase-A, low-voltage phase-B, and low-voltage phase-C.

3. The online diagnostic method for deformation position on transformer winding according to claim 2, wherein the online monitoring indicators of the high-voltage phase-A are high-voltage phase-A current, high-voltage phase-A voltage, high-voltage phases A/B current difference, and high-voltage phases A/B voltage difference;
the online monitoring indicators of high-voltage phase-B are high-voltage phase-B current, high-voltage phase-B voltage, high-voltage phases A/B current difference, and high-voltage phases A/B voltage difference;
the online monitoring indicators of high-voltage phase-C are high-voltage phase-B current, high-voltage phase-B voltage, high-voltage phases B/C current difference, and high-voltage phases B/C voltage difference;
the online monitoring indicators of medium-voltage phase-A are medium-voltage phase-A current, medium-voltage phase-A voltage, medium-voltage phases A/B current difference and medium-voltage phases A/B voltage difference;
the online monitoring indicators of medium-voltage phase-B are medium-voltage phase-B current, medium-voltage phase-B voltage, medium-voltage phases A/B current difference and medium-voltage phases A/B voltage difference;
the online monitoring indicators of medium-voltage phase-C are medium-voltage phase-B current, medium-voltage phase-B voltage, medium-voltage phases B/C current difference and medium-voltage phases B/C voltage difference;
the online monitoring indicators of low-voltage phase-A are low-voltage phase-A current, low-voltage phase-A voltage, low-voltage phases A/B current difference, and low-voltage phases A/B voltage difference;
the on-line monitoring indicators of low-voltage phase-B are low-voltage phase-B current, low-voltage phase-B voltage, low-voltage phases A/B current difference, and low-voltage phases A/B voltage difference; and
the on-line monitoring indicators of the low-voltage phase-C are low-voltage phase-B current, low-voltage phase-B voltage, low-voltage phases B/C current difference, and low-voltage phases B/C voltage difference.

4. The online diagnostic method for deformation position on transformer winding according to claim 1, wherein the dividing online monitoring data recorded according to the online monitoring indicators into two sequences according to time comprises: for the transformer that has subjected to short circuit, dividing, according to occurrence time of a latest short circuit, the online monitoring data into a front-segment sequence before the short-circuit and a back-segment sequence after the short-circuit; and for the transformer that has not subjected to short-circuit, dividing, according to time length, the online monitoring data into a front-segment sequence and a back-segment sequence.

5. The online diagnostic method for deformation position on transformer winding according to claim 1, wherein the normalization may be maximum or minimum normalization, and the online monitoring data may be converted into [0, 1] interval by following formula to obtain the non-dimensional online monitoring data x*:
$${x}^{*} = \frac{x - {x}_{min}}{{x}_{max} - {x}_{min}}$$
where x is the online monitoring data recorded according to the online monitoring indicators, xₘₐₓ is a maximum value of the online monitoring data recorded according to a same online monitoring indicator, and xₘᵢₙ is a minimum value of the online monitoring data recorded according to the same online monitoring indicator.

6. The online diagnostic method for deformation position on transformer winding according to claim 1, wherein the diagnostic model training comprises: finding a hyperplane that is able to separate deformation data and normal data and maximizes an interval between these two types of data.

7. The online diagnostic method for deformation position on transformer winding according to claim 6, wherein performing diagnose on the positions corresponding to respective position subsamples to determine whether there is a winding deformation comprises: if a subsample point to be diagnosed is located on a deformation side of the hyperplane, it is determined that a deformation occurs at the position; and if the subsample point to be diagnosed is located on a normal side of the hyperplane, it is determined that no deformation occurs at the position.
